(19) United States
(12) Patent Application Publication
(10) Pub. No.: US 2026/0339025 A1
(43) Pub. Date: Oct. 29, 2026

(54) STRUCTURES ENABLING DIAGONAL LIGHT TRANSFER TO A PHOTODETECTOR

(71) Applicant: GlobalFoundries U.S. Inc., Malta, NY (US)

(72) Inventors: Yusheng Bian, Ballston Lake, NY (US); Xiaoxiao Zhang, Ballston Lake, NY (US); Judson R. Holt, Ballston Lake, NY (US); Won Suk Lee, Malta, NY (US); Abdelsalam Aboketaf, Essex Junction, VT (US)

(21) Appl. No.: 19/189,343

(22) Filed: Apr. 25, 2025

(51) Int. Cl. G02B 6/122; G02B 6/125; H10F 30/225; H10F 77/40

(52) U.S. Cl. CPC G02B 6/1228; G02B 6/125; H10F 30/225; H10F 77/413

(57) ABSTRACT

Structures including a photodetector and methods of forming a structure including a photodetector. The structure comprises a photodetector including a pad comprising a semiconductor material, a first doped region in the pad, a second doped region in the pad, and a semiconductor layer on the pad. The structure further comprises a waveguide core that overlies the photodetector. The waveguide core including a tapered section that overlaps with a portion of the semiconductor layer and with a portion of the first doped region that is adjacent to the portion of the semiconductor layer.

### BACKGROUND

This disclosure relates to photonic chips and, more specifically, to structures including a photodetector and methods of forming such structures.

Photonic chips are used in many applications and systems including, but not limited to, data communication systems and data computation systems. A photonic chip includes a photonic integrated circuit comprised of photonic components, such as modulators, polarizers, and couplers, that are used to manipulate light received from a light source, such as an optical fiber or a laser. A photodetector may be utilized in the photonic integrated circuit to convert light, which may be modulated as an optical signal, into an electrical signal.

Conventional lateral photodetectors may be butt coupled to a waveguide core that supplies the light to be converted to the electrical signal. Such conventional lateral photodetectors may experience performance degradation at high optical power. For example, a conventional lateral photodetector may exhibit significant bandwidth roll off and responsivity compression/saturation issues at high optical power, which may significantly compromise system level performance for high-speed applications. In addition, a conventional lateral photodetector that is butt coupled to a waveguide core may exhibit excessive back reflection.

Improved structures including a photodetector and methods of forming such structures are needed.

### SUMMARY

In an embodiment of the invention, a structure for a photonic chip is provided. The structure comprises a photodetector including a pad comprising a semiconductor material, a first doped region in the pad, a second doped region in the pad, and a semiconductor layer on the pad. The structure further comprises a waveguide core that overlies the photodetector. The waveguide core including a tapered section that overlaps with a portion of the semiconductor layer and with a portion of the first doped region that is adjacent to the portion of the semiconductor layer.

In an embodiment of the invention, a method of forming a structure for a photonic chip is provided. The method comprises forming a photodetector that includes a pad comprising a semiconductor material, a first doped region in the pad, a second doped region in the pad, and a semiconductor layer on the pad. The method further comprises forming a waveguide core that overlies the photodetector. The waveguide core includes a tapered section that overlaps with a portion of the semiconductor layer and with a portion of the first doped region that is adjacent to the portion of the semiconductor layer.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a top view of a structure at an initial fabrication stage of a processing method in accordance with embodiments of the invention.

FIG. 1A is a cross-sectional view taken generally along line 1A-1A in FIG. 1.

FIG. 2 is a top view of the structure at a fabrication stage of the processing method subsequent to FIGS. 1, 1A.

FIG. 2A is a cross-sectional view taken generally along line 2A-2A in FIG. 2.

FIG. 3 is a cross-sectional view of the structure at a fabrication stage of the processing method subsequent to FIGS. 2, 2A.

FIG. 4 is a cross-sectional view of a structure in accordance with alternative embodiments of the invention.

FIG. 5 is a top view of a structure in accordance with alternative embodiments of the invention.

FIG. 5A is a cross-sectional view taken generally along line 5A-5A in FIG. 5.

FIG. 6 is a top view of a structure in accordance with alternative embodiments of the invention.

FIG. 6A is a cross-sectional view taken generally along line 6A-6A in FIG. 6.

FIG. 7 is a top view of a structure in accordance with alternative embodiments of the invention.

FIG. 7A is a cross-sectional view taken generally along line 7A-7A in FIG. 7.

FIG. 8 is a top view of a structure in accordance with alternative embodiments of the invention.

### DETAILED DESCRIPTION

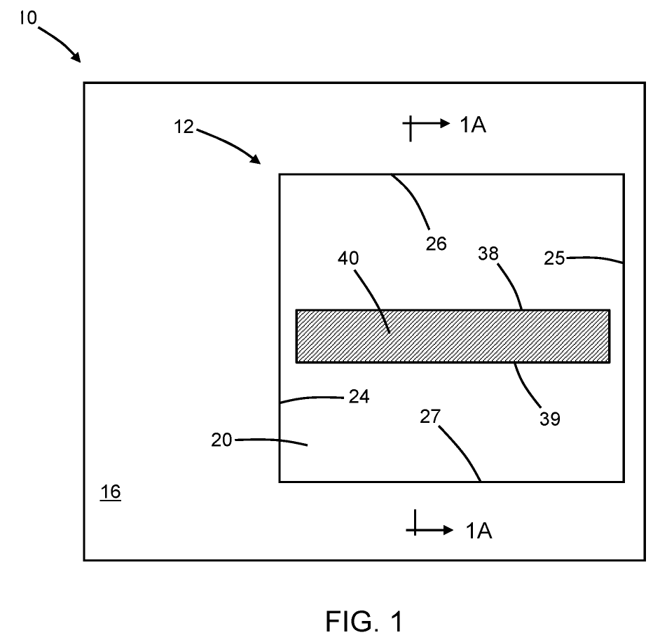

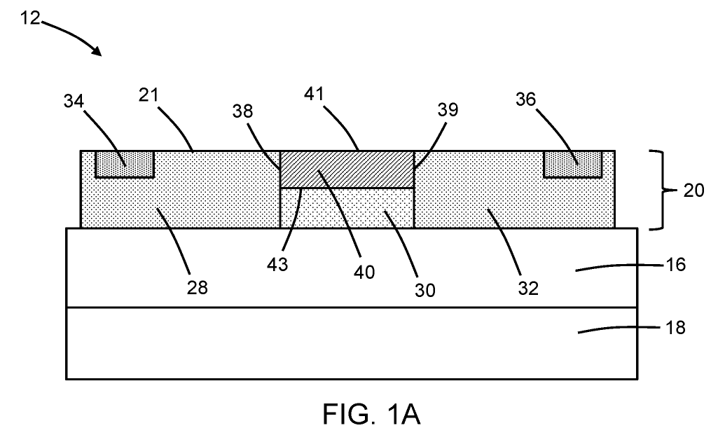

With reference to FIGS. 1, 1A and in accordance with embodiments of the invention, a structure 10 for a photonic chip may include a photodetector 12. The photodetector 12 is positioned on, and overlies, a dielectric layer 16 and a semiconductor substrate 18. In an embodiment, the dielectric layer 16 may be comprised of a dielectric material, such as an oxide of silicon (e.g., silicon dioxide), and the semiconductor substrate 18 may be comprised of a semiconductor material, such as single-crystal silicon. In an embodiment, the dielectric layer 16 may be a buried oxide layer of a silicon-on-insulator substrate. The dielectric layer 16 may provide low-index cladding that separates the photodetector 12 from the semiconductor substrate 18.

The photodetector 12 includes a pad 20 that is positioned on the dielectric layer 16. The pad 20 includes a top surface 21, a side edge 24, a side edge 25 opposite from the side edge 24, a side edge 26, and a side edge 27 opposite from the side edge 26. The side edges 24, 25, 26, 27 surround an outer perimeter of the pad 20. In an embodiment, the pad 20 may be comprised of a material having a refractive index that is greater than the refractive index of silicon dioxide. In an embodiment, the pad 20 may be comprised of a semiconductor material. In an embodiment, the pad 20 may be comprised of single-crystal silicon. The pad 20 may be formed by patterning a layer comprised of its constituent semiconductor material with lithography and etching processes. In an embodiment, the pad 20 may be formed by patterning the semiconductor material, which may be single-crystal silicon, of the device layer of a silicon-on-insulator substrate.

The pad 20 may include a doped region 28, an undoped region 30, and a doped region 32. The doped region 28 may have an opposite conductivity type from the doped region 32. The undoped region 30 is comprised of intrinsic semiconductor material. The undoped region 30 is arranged in a lateral direction between the doped region 28 and the doped region 32. The doped region 28 may be formed by, for example, ion implantation with an implantation mask with an opening that determines an implanted area of the pad 20. The implantation mask may include a layer of photoresist applied by a spin-coating process, pre-baked, exposed to light projected through a photomask, baked after exposure, and developed with a chemical developer to define the opening over the area of the pad 20 to be implanted. The implantation conditions, such as ion species, dose, and kinetic energy, may be selected to tune the electrical and physical characteristics of the doped region 28. The implantation mask may be stripped after forming the doped region 28. In an embodiment, the semiconductor material of the doped region 28 may contain an n-type dopant, such as arsenic or phosphorus, that provides n-type electrical conductivity.

The doped region 32 may be formed by, for example, ion implantation with an implantation mask with an opening that determines an implanted area of the pad 20. The implantation mask may include a layer of photoresist applied by a spin-coating process, pre-baked, exposed to light projected through a photomask, baked after exposure, and developed with a chemical developer to define the opening over the area of the pad 20 to be implanted. The implantation conditions, such as ion species, dose, and kinetic energy, may be selected to tune the electrical and physical characteristics of the doped region 32. The implantation mask may be stripped after forming the doped region 32. In an embodiment, the semiconductor material of the doped region 32 may contain a p-type dopant, such as boron, that provides p-type electrical conductivity.

A doped region 34 may be formed by masked ion implantation in a portion of the doped region 28. The doped region 34 may have the same conductivity type (e.g., n-type) as the doped region 28 but at a higher dopant concentration. A doped region 36 may be formed by masked ion implantation in a portion of the doped region 32. The doped region 36 may have the same conductivity type (e.g., p-type) as the doped region 32 but at a higher dopant concentration.

The photodetector 12 further includes a semiconductor layer 40 representing a light-absorbing region that is formed in a recess 43 patterned by lithography and etching processes in the pad 20. The recess 43 holding the semiconductor layer 40 may extend partially through the undoped region 30. The semiconductor layer 40 may have a sidewall 38, a sidewall 39 opposite from the sidewall 38, and a top surface 41. The doped region 28 is laterally arranged between the sidewall 38 of the semiconductor layer 40 and the side edge 26 of the pad 20. In an embodiment, the top surface 41 of the semiconductor layer 40 may be coplanar with the top surface 21 of the pad 20 such that the semiconductor layer 40 is fully embedded in the pad 20. In an embodiment, the top surface 41 of the semiconductor layer 40 may be substantially coplanar with the top surface 21 of the pad 20.

The sidewall 38 is arranged adjacent to the doped region 28. In an embodiment, the doped region 28 may adjoin the sidewall 38 along a vertical interface. In an embodiment, the doped region 28 may be laterally offset within the pad 20 such that a portion of the pad 20 is undoped between the doped region 28 and the sidewall 38 of the semiconductor layer 40. In an embodiment, a portion of the semiconductor layer 40 adjacent to the sidewall 38 may receive dopant when the doped region 28 is formed.

The sidewall 39 is arranged adjacent to the doped region 32. In an embodiment, the doped region 32 may adjoin the sidewall 39 along a vertical interface. In an embodiment, the doped region 32 may be laterally offset within the pad 20 such that a portion of the pad 20 is undoped between the doped region 32 and the sidewall 39 of the semiconductor layer 40. In an embodiment, a portion of the semiconductor layer 40 adjacent to the sidewall 39 may receive dopant when the doped region 32 is formed.

The semiconductor layer 40 of the photodetector 12 may be comprised of a light-absorbing material that is configured to absorb light of a given wavelength, such as a wavelength within an infrared wavelength band of the electromagnetic spectrum, and to generate charge carriers from photons of the absorbed light by photoelectric conversion. In an embodiment, the semiconductor layer 40 may be comprised of a different material from the pad 20. In an embodiment, the semiconductor layer 40 may be comprised of a material having a composition that includes germanium. In an embodiment, the semiconductor layer 40 may be comprised of intrinsic germanium that is undoped. In an embodiment, the semiconductor layer 40 may be comprised of a III-V compound semiconductor material. In an embodiment, the semiconductor layer 40 may be comprised of intrinsic silicon.

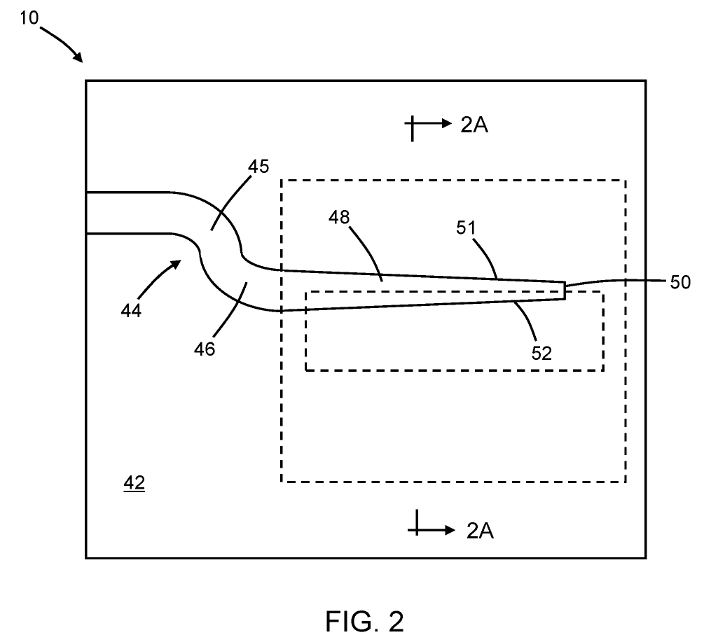

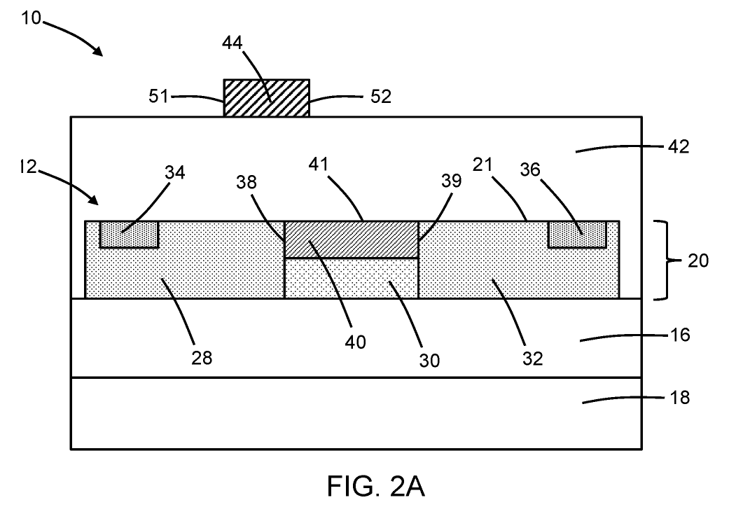

With reference to FIGS. 2, 2A in which like reference numerals refer to like features in FIGS. 1, 1A and at a subsequent fabrication stage, the structure 10 includes a dielectric layer 42 that overlies the photodetector 12. The dielectric layer 42 may be comprised of a dielectric material, such as an oxide of silicon (e.g., silicon dioxide), having a refractive index that is less than the refractive index of the material constituting the pad 20.

The structure 10 further includes a waveguide core 44 that is arranged on the dielectric layer 42 and that includes a tapered section 48 overlying a portion of the photodetector 12. A portion of the dielectric layer 42 is arranged between the tapered section 48 and both the pad 20 and the semiconductor layer 40 such that the tapered section 48 has a non-contacting relationship. The waveguide core 44 may include a set of bends 45, 46, and the tapered section 48 is connected to the bend 46. The bends 45, 46 route the waveguide core 44 such that the waveguide core 44 extends across the side edge 24 of the pad 20 adjacent to the semiconductor layer 40. The bends 45, 46 represent curved features that promote adiabatic coupling of light to the photodetector 12. The tapered section 48 may terminate at an end 50 that overlies the pad 20.

The tapered section 48 of the waveguide core 44 may overlap with a portion of the semiconductor layer 40 adjacent to the sidewall 38 of the semiconductor layer 40 and also may overlap with a portion of the pad 20 that includes the doped region 28. A non-overlapped portion of the semiconductor layer 40 is laterally arranged between the overlapped portion and the sidewall 39 of the semiconductor layer 40.

The tapered section 48 may have a sidewall 51 and a sidewall 52 opposite from the sidewall 51. The sidewall 52 of the tapered section 48 may overlap with the semiconductor layer 40, and the sidewall 51 of the tapered section 48 may be offset from the semiconductor layer 40 and overlap with the doped region 28. In that regard, the sidewall 52 of the tapered section 48 may be laterally arranged between the sidewall 38 of the semiconductor layer 40 and the sidewall 39 of the semiconductor layer 40. The non-overlapped portion of the semiconductor layer 40 is laterally arranged between the sidewall 52 of the tapered section 48 and the sidewall 39 of the semiconductor layer 40.

The tapered section 48 of the waveguide core 44 may have a width dimension that decreases with increasing distance from the side edge 24. In an embodiment, the width dimension of the tapered section 48 of the waveguide core 44 may decrease linearly with decreasing distance from the side edge 24. In an alternative embodiment, the width dimension of the tapered section 48 may vary based on a non-linear function, such as a quadratic function, a cubic function, a parabolic function, a sine function, a cosine function, a Bezier function, or an exponential function. In an embodiment, the tapered section 48 may include a single stage of tapering characterized by a taper angle. In an alternative embodiment, the tapered section 48 may taper in multiple stages each characterized by a different taper angle.

In an embodiment, the refractive index of the material constituting the waveguide core 44 may be greater than the refractive index of the material constituting the dielectric layer 42. In an embodiment, the waveguide core 44 may be comprised of a dielectric material, such as silicon nitride, silicon oxynitride, or aluminum nitride. In an embodiment, the waveguide core 44 may be comprised of a semiconductor material, such as polycrystalline silicon or amorphous silicon. In an embodiment, the waveguide core 44 may be formed by depositing a layer comprised of its constituent material and patterning the layer with lithography and etching processes. In an alternative embodiment, a thin slab layer may be coupled to a lower portion of the waveguide core 44 and may be formed by partially etching the waveguide core 44 with lithography and etching processes.

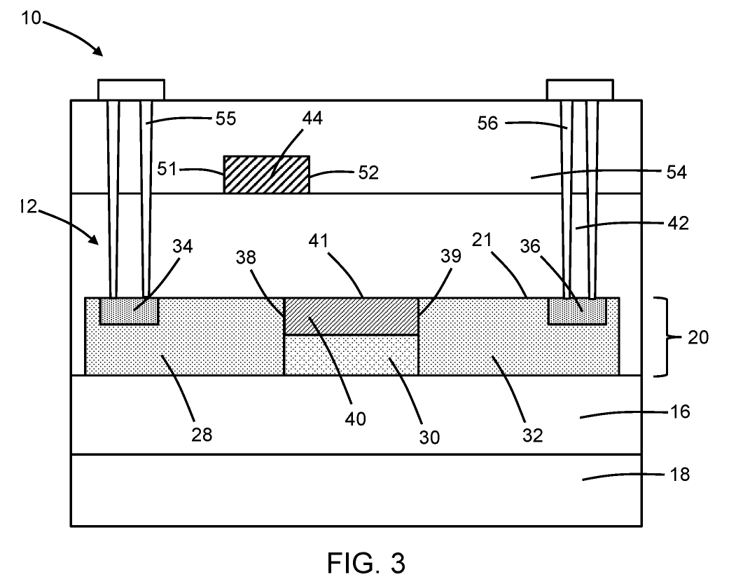

With reference to FIG. 3 in which like reference numerals refer to like features in FIG. 2, 2A and at a subsequent fabrication stage, a dielectric layer 54 may be formed over the waveguide core 44. The dielectric layer 54 may be comprised of a dielectric material, such as an oxide of silicon (e.g., silicon dioxide), having a refractive index that is less than the refractive index of the material constituting the waveguide core 44.

Contacts 55 may be formed that are coupled by the doped region 34 to the doped region 28, and contacts 56 may be formed that are coupled by the doped region 36 to the doped region 32. The contacts 55, 56 may be comprised of a metal, such as tungsten. The contacts 55, 56 may be used to supply a bias voltage to the photodetector 12 and to thereby collect charge carriers during operation of the photodetector 12.

In use, light propagating in the waveguide core 44 is diagonally coupled from the tapered section 48 of the waveguide core 44 to the semiconductor layer 40 of the photodetector 12. In an embodiment, the light received by the photodetector 12 may be laser light that is modulated as an optical signal. The semiconductor layer 40 of the photodetector 12 absorbs photons of the light and converts the absorbed photons into charge carriers by photoelectric conversion. The bias voltage applied to the doped regions 32, 34 causes the charge carriers to be collected and output to provide, as a function of time, a measurable photocurrent.

The structure 10 leverages a waveguide core 44 is placed diagonally in a different level (in elevation) from the photodetector 12 to provide diagonal coupling of light from the waveguide core 44 to the semiconductor layer 40 of the photodetector 12. The photodetector 12 may exhibit a lowered performance degradation at high optical power in comparison with a conventional lateral photodetector that is butt coupled to a waveguide core. For example, the photodetector 12 may exhibit a reduced bandwidth roll off and reduced responsivity compression/saturation issues at high optical power in comparison with a conventional lateral photodetector that is butt coupled to a waveguide core, which may benefit system level performance for high-speed applications. In addition, the photodetector 12 may exhibit a reduced back reflection in comparison with a conventional lateral photodetector that is butt coupled to a waveguide core.

In an embodiment, the waveguide core 44 may directly couple the photodetector 12 to an edge coupler to construct a polarization-independent receiver. The polarization-independent receiver may be characterized by a responsivity and an insertion loss that are comparable for light with either transverse electric polarization or transverse magnetic polarization.

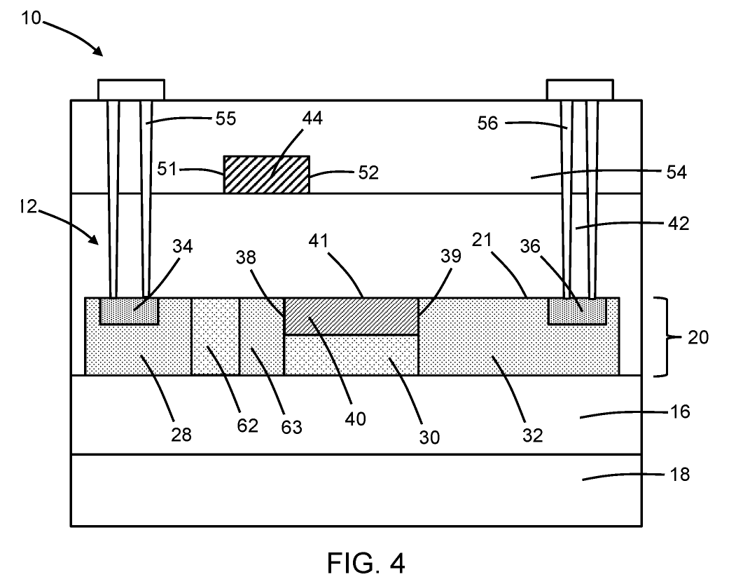

With reference to FIG. 4 and in accordance with alternative embodiments, the photodetector 12 may be configured as a lateral avalanche photodetector that further integrates a multiplication layer 62 and a charge layer 63 between the semiconductor layer 40 and the doped region 28. In an alternative embodiment, the photodetector 12 may have a vertical arrangement instead of a lateral arrangement. Specifically, the photodetector 12 may be configured as a vertical photodetector or as a vertical avalanche photodetector.

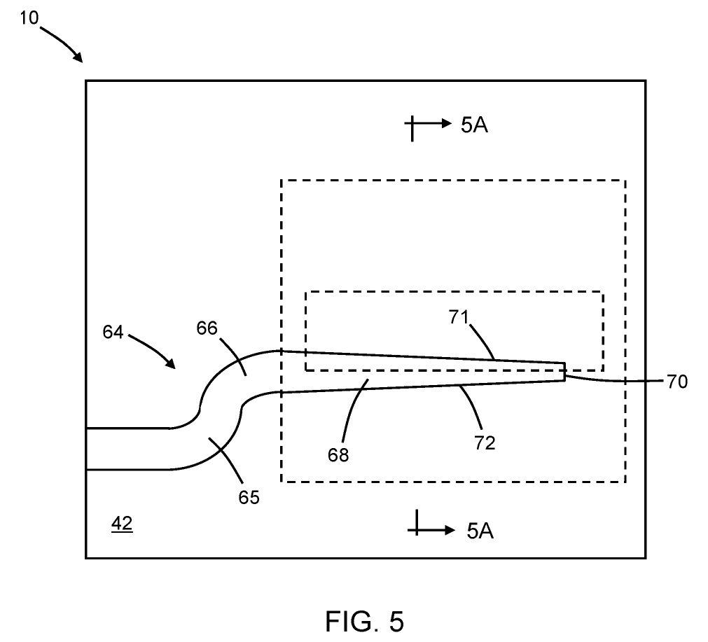

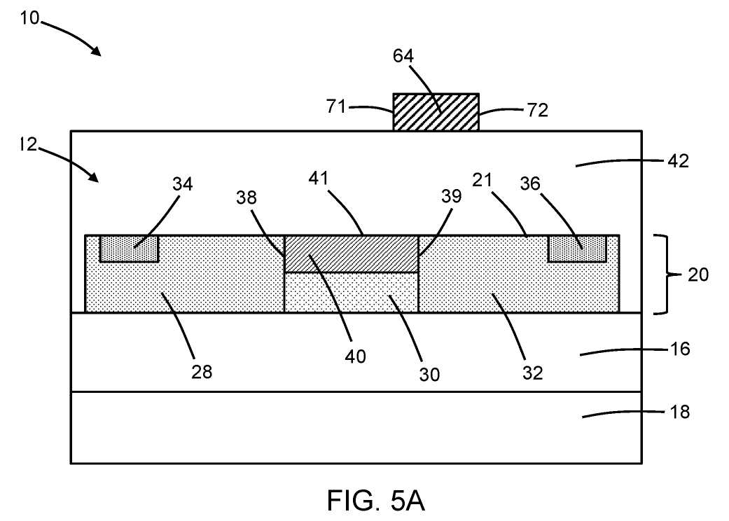

With reference to FIGS. 5, 5A and in accordance with alternative embodiments, the structure 10 may include a waveguide core 64 that is arranged on the dielectric layer 42 and that includes a tapered section 68 overlying a portion of the photodetector 12. A portion of the dielectric layer 42 is arranged between the tapered section 68 and both the pad 20 and the semiconductor layer 40 such that the tapered section 68 has a non-contacting relationship. The waveguide core 64 may include a set of bends 65, 66 and a tapered section 68 that is connected to the bend 66. The bends 65, 66 route the waveguide core 64 such that the waveguide core 64 extends across the side edge 24 of the pad 20. The bends 65, 66 represent curved features that promote adiabatic coupling of light to the photodetector 12. The tapered section 68 may terminate at an end 70 that overlies the pad 20.

The tapered section 68 of the waveguide core 64 may overlap with a portion of the semiconductor layer 40 adjacent to the sidewall 39 of the semiconductor layer 40 and also may overlap with a portion of the pad 20 that includes the doped region 32. A non-overlapped portion of the semiconductor layer 40 is laterally arranged between the overlapped portion and the sidewall 38 of the semiconductor layer 40.

The tapered section 68 may have a sidewall 71 and a sidewall 72 opposite from the sidewall 71. The sidewall 71 of the tapered section 68 may overlap with the semiconductor layer 40, and the sidewall 72 of the tapered section 68 may be offset from the semiconductor layer 40 and overlap with the doped region 32. In that regard, the sidewall 71 of the tapered section 68 may be laterally arranged between the sidewall 38 of the semiconductor layer 40 and the sidewall 39 of the semiconductor layer 40. The non-overlapped portion of the semiconductor layer 40 is laterally arranged between the sidewall 72 of the tapered section 68 and the sidewall 39 of the semiconductor layer 40.

The tapered section 68 of the waveguide core 64 may have a width dimension that decreases with increasing distance from the side edge 24. In an embodiment, the width dimension of the tapered section 68 of the waveguide core 64 may decrease linearly with decreasing distance from the side edge 24. In an alternative embodiment, the width dimension of the tapered section 68 may vary based on a non-linear function, such as a quadratic function, a cubic function, a parabolic function, a sine function, a cosine function, a Bezier function, or an exponential function. In an embodiment, the tapered section 68 may include a single stage of tapering characterized by a taper angle. In an alternative embodiment, the tapered section 68 may taper in multiple stages each characterized by a different taper angle.

In an embodiment, the refractive index of the material constituting the waveguide core 64 may be greater than the refractive index of the material constituting the dielectric layer 42. In an embodiment, the waveguide core 64 may be comprised of a dielectric material, such as silicon nitride, silicon oxynitride, or aluminum nitride. In an embodiment, the waveguide core 64 may be comprised of a semiconductor material, such as polycrystalline silicon or amorphous silicon. In an embodiment, the waveguide core 64 may be formed by depositing a layer comprised of its constituent material and patterning the layer with lithography and etching processes. In an alternative embodiment, a thin slab layer may be coupled to a lower portion of the waveguide core 64 and may be formed by partially etching the waveguide core 64 with lithography and etching processes.

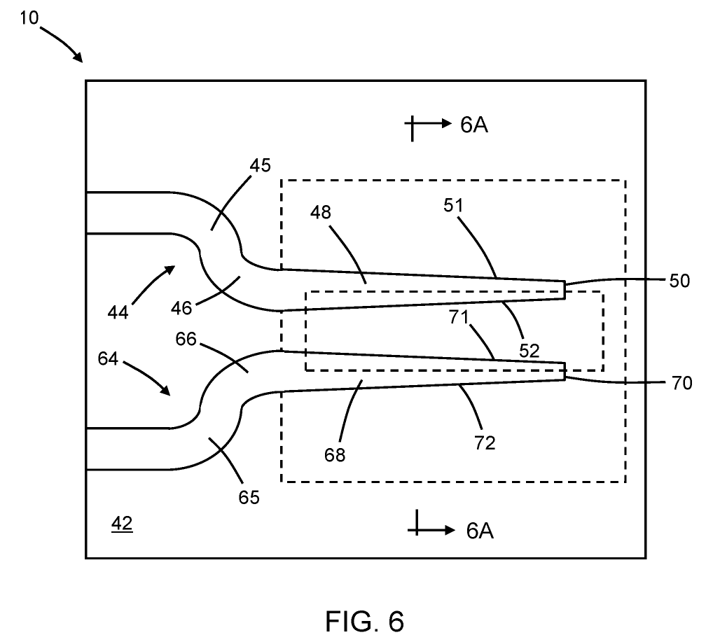

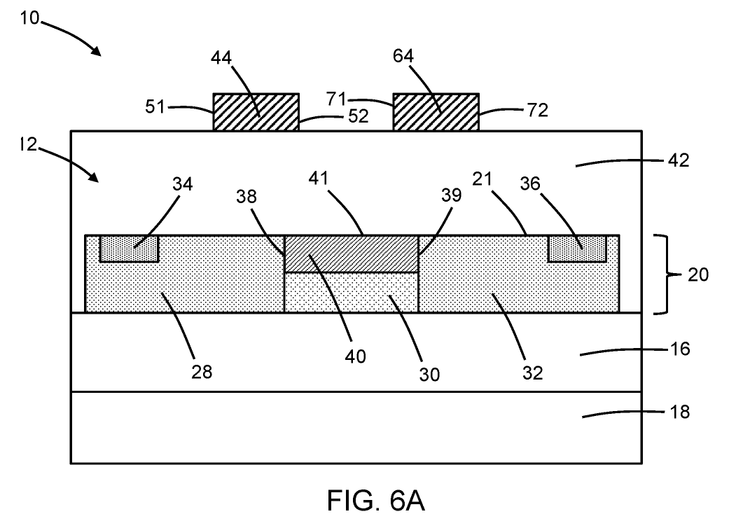

With reference to FIGS. 6, 6A and in accordance with alternative embodiments, the structure 10 may include the waveguide core 44 and the waveguide core 64. In an embodiment, the waveguide core 44 and the waveguide core 64 may both extend across the side edge 24 of the pad 20. The sidewall 52 of the tapered section 48 may overlap with the semiconductor layer 40, and the sidewall 51 of the tapered section 48 may be offset from the semiconductor layer 40 and overlie the doped region 28. The sidewall 71 of the tapered section 68 may overlap with the semiconductor layer 40, and the sidewall 72 of the tapered section 68 may be offset from the semiconductor layer 40 and overlie the doped region 32.

Light may be supplied to the waveguide core 44 and the waveguide core 64 from an optical splitter. For example, the optical splitter may be a multimode interference splitter with an output port coupled to the waveguide core 44 and a separate output port coupled to the waveguide core 64.

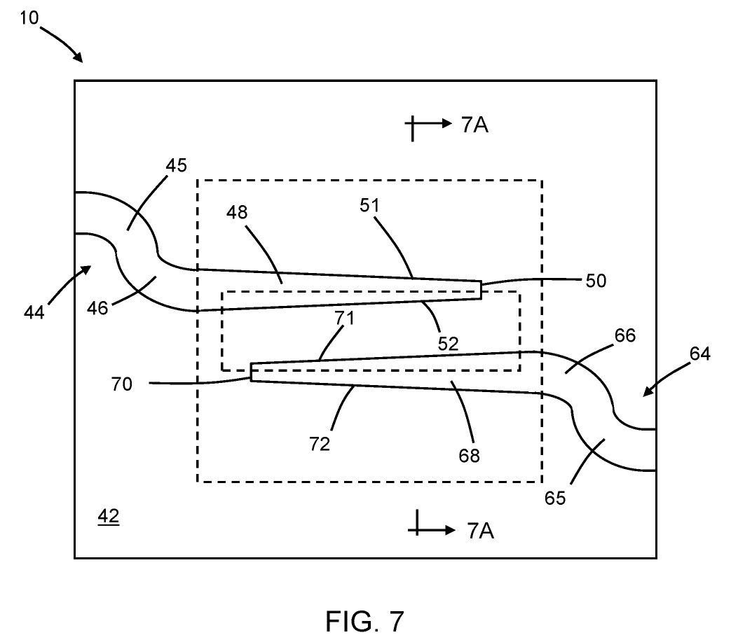

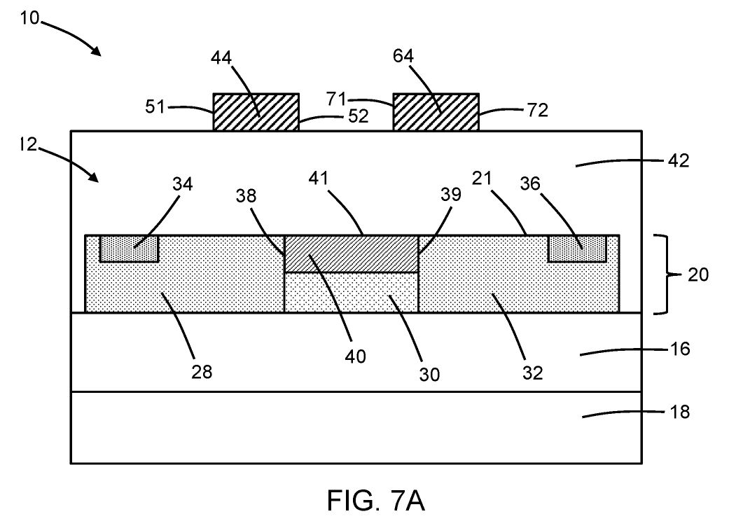

With reference to FIGS. 7, 7A and in accordance with alternative embodiments, the structure 10 may include the waveguide core 44 and the waveguide core 64 that partially overlap with different portions of the semiconductor layer 40. In an embodiment, the waveguide core 44 may extend across the side edge 24 of the pad 20, and the waveguide core 64 may extend across the side edge 25 of the pad 20. The sidewall 52 of the tapered section 48 may overlap with the semiconductor layer 40, and the sidewall 51 of the tapered section 48 may be offset from the semiconductor layer 40 and overlie the doped region 28. The sidewall 71 of the tapered section 68 may overlap with the semiconductor layer 40, and the sidewall 72 of the tapered section 68 may be offset from the semiconductor layer 40 and overlie the doped region 32.

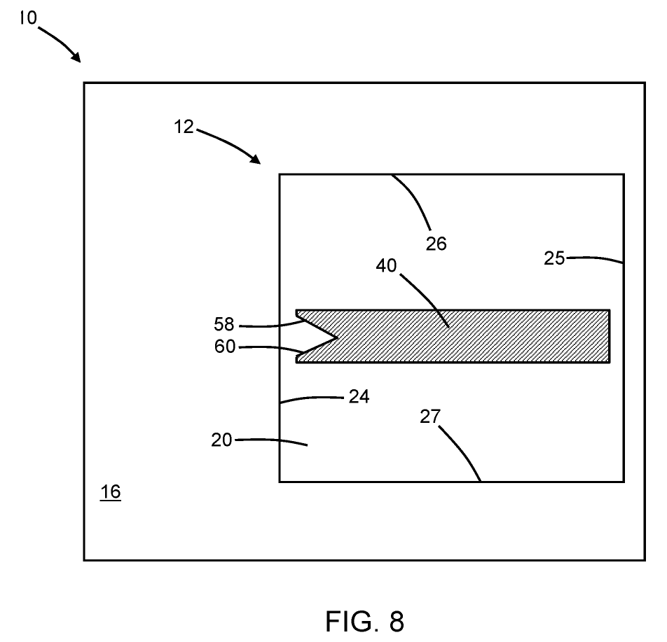

With reference to FIG. 8 and in accordance with alternative embodiments, the semiconductor layer 40 may have an end with a concavity that is bounded by a surface 58 and a surface 60. The surfaces 58, 60, which are sloped relative to each other and may intersect, may function to reduce optical return loss. In an alternative embodiment, the end of the semiconductor layer 40 may include a convexity in the form of a narrowed tip portion instead of a concavity. In an alternative embodiment, the end of the semiconductor layer 40 may include a quadrilateral shape, instead of a concavity, with additional surfaces.

The waveguide core 44 and/or the waveguide core 64, as well as the dielectric layer 42, may be formed that overlie the photodetector 12 with the surfaces 58, 60. In an embodiment, the end of the semiconductor layer 40 including the concavity may be positioned adjacent to the side edge 24 of the pad 20. In an alternative embodiment, the opposite end of the semiconductor layer 40, which is adjacent to the side edge 25 of the pad 20, may include a concavity, a convexity, or a quadrilateral shape.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/- 10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. A feature may “overlie” another feature if the feature is positioned in elevation over another feature. Different features may “overlap” if a feature extends over, and covers all or a part of, another feature. A feature may “underlie” another feature if the feature is positioned in elevation below another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure for a photonic chip, the structure comprising:
a photodetector including a pad comprising a semiconductor material, a first doped region in the pad, a second doped region in the pad, and a semiconductor layer on the pad; and
a first waveguide core that overlies the photodetector, the first waveguide core including a first tapered section that overlaps with a first portion of the semiconductor layer and with a portion of the first doped region that is adjacent to the first portion of the semiconductor layer.

2. The structure of claim 1 wherein the first tapered section has a first sidewall, and the first sidewall of the first tapered section overlaps with the semiconductor layer.

3. The structure of claim 2 wherein the first tapered section has a second sidewall opposite from the first sidewall, and the second sidewall of the first tapered section overlaps with the first doped region.

4. The structure of claim 2 wherein the semiconductor layer has a first sidewall and a second sidewall opposite from the first sidewall, and the first sidewall of the first tapered section is laterally arranged between the first sidewall of the semiconductor layer and the second sidewall of the semiconductor layer.

5. The structure of claim 4 wherein the semiconductor layer has a second portion laterally arranged between the first sidewall of the first tapered section and the second sidewall of the semiconductor layer.

6. The structure of claim 1 wherein the pad has a side edge, and the first waveguide core extends across the side edge of the pad.

7. The structure of claim 6 wherein the first tapered section has a width dimension that decreases with increasing distance from the side edge of the pad.

8. The structure of claim 1 further comprising:
a second waveguide core including a second tapered section that overlaps with a second portion of the semiconductor layer and with a portion of the second doped region that is adjacent to the second portion of the semiconductor layer.

9. The structure of claim 8 wherein the pad has a side edge, the first waveguide core extends across the side edge of the pad, and the second waveguide core extends across the side edge of the pad.

10. The structure of claim 8 wherein the pad has a first side edge and a second side edge opposite from the first side edge, the first waveguide core extends across the first side edge of the pad, and the second waveguide core extends across the second side edge of the pad.

11. The structure of claim 1 wherein the first waveguide core includes a plurality of bends that are coupled to the first tapered section.

12. The structure of claim 1 further comprising:
a dielectric layer positioned between the semiconductor layer and the first tapered section.

13. The structure of claim 1 wherein the semiconductor layer comprises germanium, and the first waveguide core comprises silicon nitride.

14. The structure of claim 1 wherein the pad has a first top surface and a recess, the semiconductor layer is positioned inside the recess, and the semiconductor layer has a second top surface that is coplanar with the first top surface.

15. The structure of claim 1 wherein the pad has a first top surface and a recess, the semiconductor layer is positioned inside the recess, and the semiconductor layer has a second top surface that is substantially coplanar with the first top surface.

16. The structure of claim 1 wherein the first doped region has a first conductivity type, and the second doped region has a second conductivity type opposite from the first conductivity type.

17. The structure of claim 16 wherein the first conductivity type is n-type, and the second conductivity type is p-type.

18. The structure of claim 16 wherein the first conductivity type is p-type, and the second conductivity type is n-type.

19. The structure of claim 1 further comprising:
a semiconductor substrate; and
a dielectric layer on the semiconductor substrate,
wherein the pad is positioned on the dielectric layer.

20. A method of forming a structure for a photonic chip, the method comprising:
forming a photodetector that includes a pad comprising a semiconductor material, a first doped region in the pad, a second doped region in the pad, and a semiconductor layer on the pad; and
forming a waveguide core that overlies the photodetector, wherein the waveguide core includes a tapered section that overlaps with a portion of the semiconductor layer and with a portion of the first doped region that is adjacent to the portion of the semiconductor layer.
